(19) United States
(12) Patent Application Publication
(10) Pub. No.: US 2025/0247989 A1
(43) Pub. Date: Jul. 31, 2025

(54) COMPUTING RACK ARCHITECTURE SYSTEM AND METHOD

(71) Applicant: Dell Products L.P., Round Rock, TX (US)

(72) Inventors: Macen Shinsato, Georgetown, TX (US); Shawn Joel Dube, Austin, TX (US)

(73) Assignee: Dell Products L.P., Round Rock, TX (US)

(21) Appl. No.: 18/423,979

(22) Filed: Jan. 26, 2024

(51) Int. Cl. H05K 7/14; H05K 7/20

(52) U.S. Cl. CPC H05K 7/1489; H05K 7/2079

(57) ABSTRACT

Embodiments of the present disclosure provide a computing rack architecture system and method in which standardized form factor electronic modules may be compatible with different types of computing racks. According to one embodiment, a computing rack architecture system and method includes a first plate mounted to a computing rack, and a second plate mounted to the computing rack at a specified distance from the first plate. The first plate, second plate, and sides of the computing rack comprise an enclosure that is configured to house a plurality of modules of an Information Handling System (IHS).

### BACKGROUND

As the value and use of information continues to increase, individuals and businesses seek additional ways to process and store information. One option available to users is Information Handling Systems (IHSs). An IHS generally processes, compiles, stores, and/or communicates information or data for business, personal, or other purposes thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Groups of IHSs may be housed within data center environments. A data center may include a large number of IHSs, such as enterprise blade servers that are stacked and installed within computing racks, which may also be referred to as racks. A data center may include large numbers of such computing racks that are organized into rows of racks. Administration of such large groups of IHSs may require teams of remote and local administrators working in shifts in order to support around-the-clock availability of the data center operations while minimizing any downtime.

Racks provide a means for densely housing relatively large numbers of individual computing devices. A principal challenge with such dense packaging often involves providing sufficient cooling for each of the computing devices. As such, many newer computing rack designs have implemented liquid cooling systems, such as liquid immersion cooling, or liquid cooling provided by cold plates that are thermally coupled to the principal heat generating components of the computing device.

### SUMMARY

Embodiments of the present disclosure provide a computing rack architecture system and method in which standardized form factor electronic modules may be compatible with different types of computing racks. According to one embodiment, a computing rack architecture system and method includes a first plate mounted to a computing rack, and a second plate mounted to the computing rack at a specified distance from the first plate. The first plate, second plate, and sides of the computing rack comprise an enclosure that is configured to house a plurality of modules of an Information Handling System (IHS).

According to another embodiment, a computing rack architecture method includes the steps of mounting a first plate mounted to a computing rack, mounting a second plate mounted to the computing rack at a specified distance from the first plate, and inserting a plurality of modules of an Information Handling System (IHS) into the enclosure. The first plate, the second plate, and sides of the computing rack comprise the enclosure.

According to yet another embodiment, an Information Handling System (IHS) includes a plurality of modules, a first plate mounted to a computing rack, and a second plate mounted to the computing rack at a specified distance from the first plate. The first plate, the second plate, and sides of the computing rack comprise an enclosure that is configured to house the modules.

### BRIEF DESCRIPTION OF THE DRAWINGS

The present invention(s) is/are illustrated by way of example and is/are not limited by the accompanying figures. Elements in the figures are illustrated for simplicity and clarity and have not necessarily been drawn to scale.

FIGS. 1A-1E illustrate an example computing rack architecture system that may be implemented on an Open Compute Project (OCP) 21 inch rack according to one embodiment of the present disclosure.

FIGS. 2A-2B illustrate another example computing rack architecture system that may be implemented on an Electronic Industries Alliance (EIA) 19 inch rack according to one embodiment of the present disclosure.

FIGS. 3A-3E illustrate an example computing rack architecture method that may be performed to implement the computing rack architecture system in a computing rack according to one embodiment of the present disclosure.

FIG. 4 illustrates an enlarged, partial, perspective view of another example computing rack architecture system that may implement air cooling according to one embodiment of the present disclosure.

FIG. 5 is a block diagram of components of an example Information Handling System (IHS), which may be embodied as one or more of the modules described herein above.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

As described previously, liquid cooling for computing racks has become an attractive alternative to air cooling due in large part to the relatively dense housing of their constituent components, which can each generate relatively large levels of heat. Liquid cooling is being adopted in many data centers due to significant reduction in operational expenditures compared to air cooled systems. Liquid cooling systems usually utilize a cold plate that replaces the CPU's heat sink in which the cold plate is cooled using flexible conduits that circulate a liquid, such as a water, or a blend of water and other water-based materials. With increasing demand for higher performance and density, next generation architectures will require direct liquid cooling (DLC). The Open Compute Project 21″ standard (OCP21) will require blind mating for DC power as well as DLC couplers/manifolds, thus increasing the overall complexity and cost of both the OCP21 system chassis and OCP 21 inch rack.

Enterprise-based computing systems are typically deployed as modular systems with standardized form factor electronic modules mounted in standardized support structures. The enclosure modules have been commonly mounted in standardized support structures such as the 19 inch racks as specified by the Electronic Industries Alliance (EIA-310-D) specification. More recently, a new standards organization called the Open Compute Project (OCP) has been formed to promote a new rack standard commonly referred to as Open Rack. OCP is a collaborative community effort focused on redesigning hardware to efficiently support the growing demands of a computer's infrastructure. Development of computing racks conforming to the OCP standard, nevertheless, has been slow to adopt. One reason is that electronic modules designed for the OCP 21 inch racks has not been heretofore backward compatible with EIA 19 inch racks. As will be described in detail herein below, embodiments of the present disclosure provide a computing rack architecture system and method in which standardized form factor electronic enclosure modules may be compatible with either EIA 19 inch racks or OCP 21 inch racks using a modular mounting plates that are simple to implement while also reducing overall implementation costs.

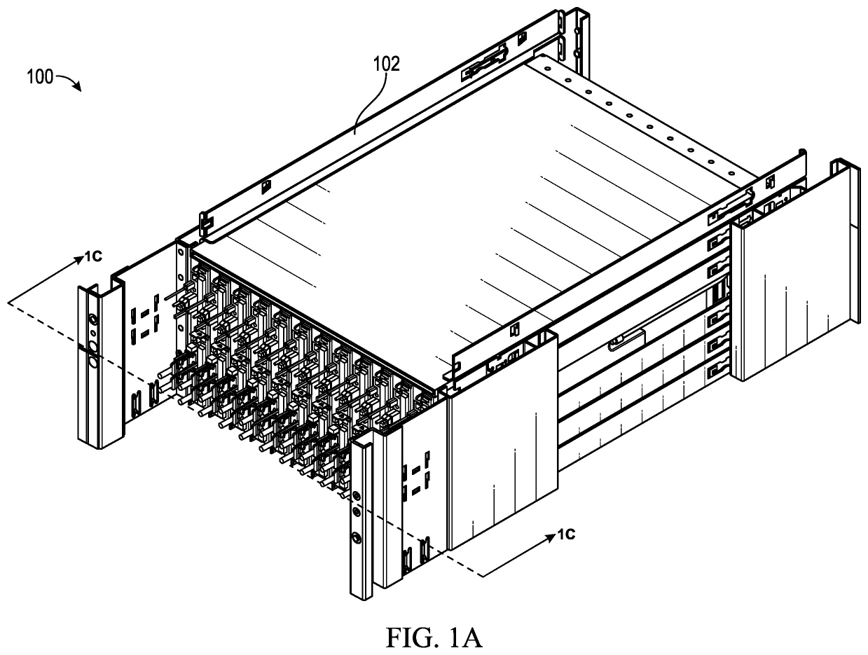

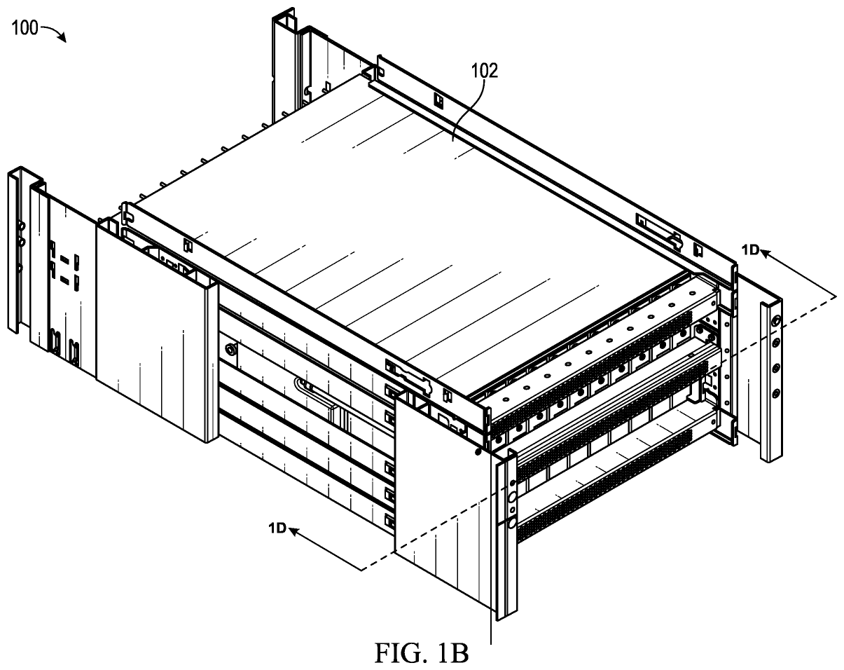

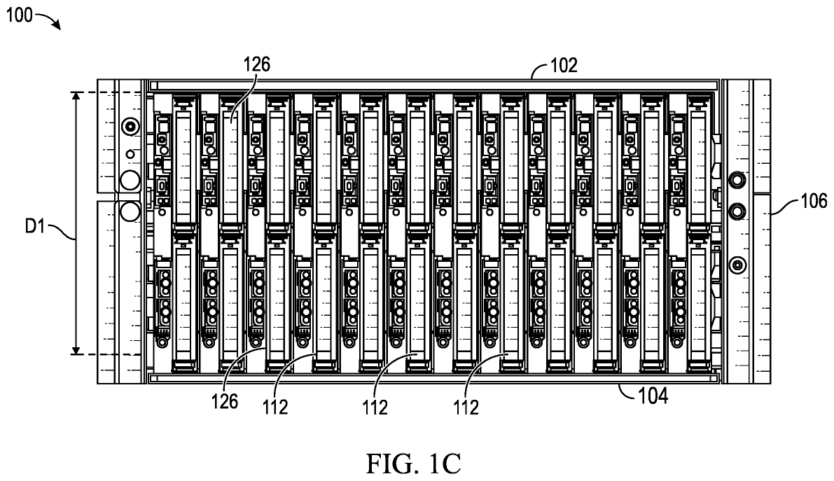

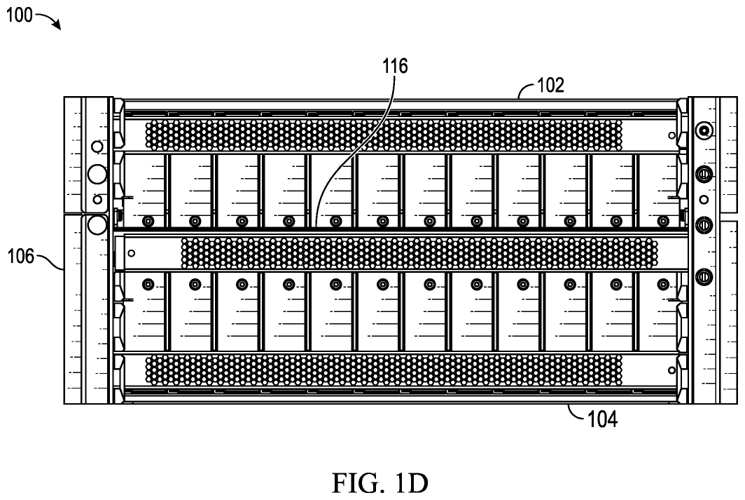

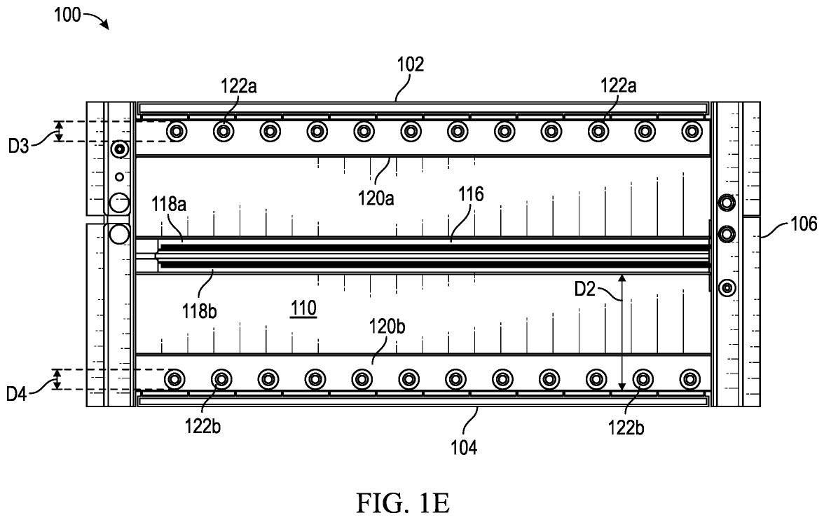

FIGS. 1A-1E illustrate an example computing rack architecture system 100 that may be implemented on an OCP 21 inch rack according to one embodiment of the present disclosure. In particular, FIG. 1A is a front perspective view of the computing rack architecture 100, FIG. 1B is a rear perspective view of the computing rack architecture 100, FIG. 1C is a front side view of the computing rack architecture 100 taken along lines 1C-1C of FIG. 1A, FIG. 1D is a rear side view of the computing rack architecture 100 taken along the lines 1D-1D of FIG. 1B, while FIG. 1E is a front side view of the computing rack architecture 100 taken along the lines 10-1C of FIG. 1A. The computing rack architecture 100 includes a top guide plate 102 and a bottom support plate 104 that are mounted on a computing rack 106, which in this particular embodiment is an OCP 21 inch rack. The top guide plate 102, bottom support plate 104, and sides of the rack 106 define an enclosure 110 for housing multiple modules 112. In particular, FIG. 1C shows the modules 112 housed within the enclosure 110, while in FIG. 1E, the modules 112 have been removed from the enclosure 110. The bottom support plate 104 is structured to support the weight of the modules 112 while the top guide plate 102 is structured to guide the modules 112 into and out of the enclosure 110.

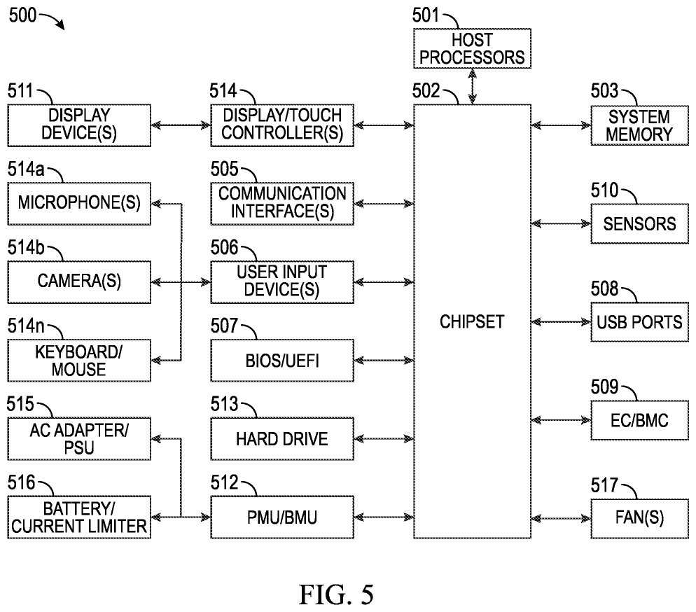

The rack 106 is generally rigid in structure such that when each of the top guide plate 102 and bottom support plate 104 are mounted to the rack 106, it maintains the top guide plate 102 and bottom support plate 104 at a specified distance D1 apart from one another. The modules 112 are dimensioned so that they can be slid into and out of the enclosure 110 based on the specified distance D1. The modules 112 may include any type of device typically installed in a computing rack. An example of such a module 112 will be described in detail herein below with reference to FIG. 5.

According to one embodiment, the computing rack architecture system 100 also includes a power bus bar 116 that is mounted to, and extends between both sides of the rack 106 as best shown in FIGS. 1D and 1E. The power bus bar 116 provides a common connection mechanism for providing electrical power to each of the modules 112 when they are inserted into the enclosure 110. The power bus bar 116, for example, may include two electrically conductive bars 118a-b that extend between both sides of the rack 106. Each module 112 may be configured with a complementary connector such that, when it is inserted into the enclosure 110, the complementary connector blind mates with the power bus bar 116 to provide electrical power for the module 112.

The power bus bar 116 is mounted at the rear side of the rack 106 at a specified distance D2 from the bottom support plate 104. The rack 106 is rigid in structure such that it maintains the power bus bar 116 at the specified distance D2 from the bottom support plate 104. That is, the power bus bar 116 is not coupled directly to the bottom support plate 104 or top guide plate 102; rather, it is directly coupled to the rear side edge of the rack 106, which is in turn, directly coupled to the bottom support plate 104 and top guide plate 102.

The computing rack architecture system 100 may also include provisions for blind mating cooling connectors for each of the modules 112. For example, an inlet direct liquid cooling (DLC) manifold 120a and an outlet DLC manifold 120b may be mounted on the rear side of the rack 106 in which each has hydraulic connectors 122a-b, respectively, that blind mate with complementary hydraulic connectors configured on each of the modules 112 when they are inserted into the enclosure 110. The inlet DLC manifold 120a may be mounted on the rear side of the rack 106 so that the rack 106 maintains the hydraulic connectors 122a at a specified distance D3 from the top guide plate 102. Additionally, the outlet DLC manifold 120b may be mounted on the rear side of the rack 106 so that the rack 106 maintains the hydraulic connectors 122b at a specified distance D4 from the bottom support plate 104. Thus, the rigid structure of the rack 106 allows the complementary hydraulic connectors configured on the modules 112 to be blind mated onto the inlet DLC manifold 120a and outlet DLC manifold 120b when the modules 112 are inserted into the enclosure 110.

The OCP standard for computing racks specify hydraulic connectors for DLC that require a relatively large level of insertion force. For example, it is estimated that the hydraulic connectors 122a-b may each require up to 30.0 pounds (Lbs.) of insertion force. Because each modules has two hydraulic connectors 122a-b, the total insertion force can exceed 60.0 pounds of insertion force. As such, insertion levers 126 may be provided on the upper and lower ends of the front of each module 112 to assist with fully inserting each module 112 into the enclosure 110.

Embodiments of the present disclosure may provide certain advantages over conventional electrical power bus and hydraulic connectors used in computing rack systems. For example, conventional power bus and hydraulic connection systems, and particularly those specified for use in OCP 21 inch racks, have used buses that extend vertically from the bottom of the rack to its upper end. This relatively long length, however, engenders problems due to the relatively long length required. Because the width of most computing racks is often substantially shorter than its height, mounting the electrical power bus 116 and hydraulic connectors 122a-b horizontally across the width of the rack requires shorter spans thus increasing their structural integrity over conventional bus systems that are mounted vertically.

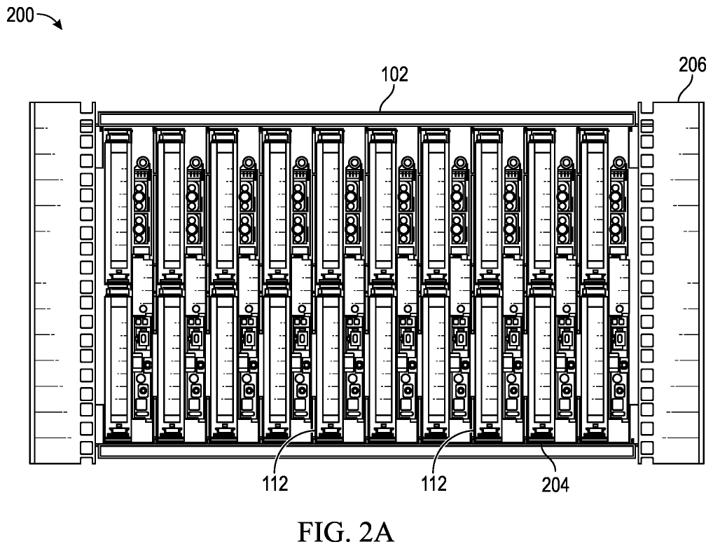

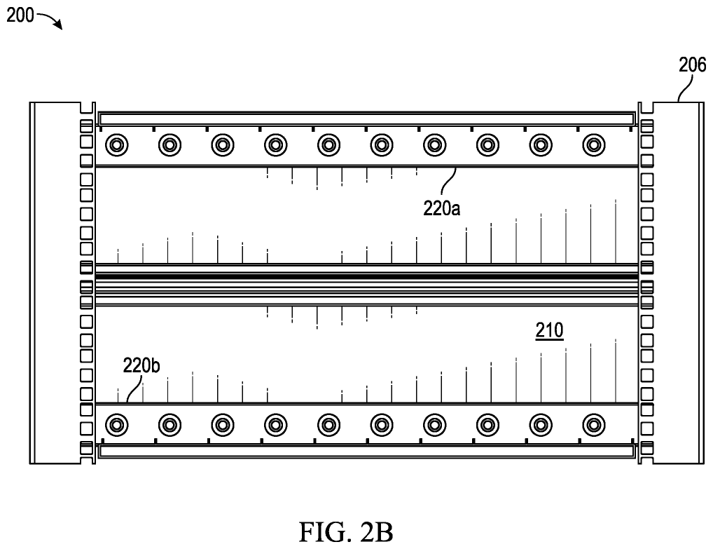

FIGS. 2A-2B illustrates another example computing rack architecture system 200 that may be implemented on an EIA 19 inch rack according to one embodiment of the present disclosure. In particular, FIG. 2A is a front side view of the computing rack architecture system 200 shown with modules 112, while FIG. 2B is a front side view of the computing rack architecture system 200 shown with the modules 112 having been removed. The computing rack architecture system 200 includes a top guide plate 202, a bottom support plate 204, an enclosure 210, a power bus bar 216, an inlet direct liquid cooling (DLC) manifold 220a and an outlet DLC manifold 220b that are similar in design and construction to the top guide plate 102, a bottom support plate 104, an enclosure 110, a power bus bar 116, an inlet direct liquid cooling (DLC) manifold 120a and an outlet DLC manifold 120b of the computing rack architecture system 100 of FIGS. 1A-1E. The top guide plate 202, a bottom support plate 204, an enclosure 210, a power bus bar 216, an inlet direct liquid cooling (DLC) manifold 220a and an outlet DLC manifold 220b differs, however, in that they are dimensioned to extend between the sides of a different type of computing rack, which in this particular embodiment, is an EIA 19 inch rack 2xx. That is, they are relatively shorter than their respective components of FIGS. 1A-1E due to the relatively shorter width of the EIA 19 inch rack 2xx.

As shown, the enclosure 210 is adapted to hold ten modules 112. This contrasts with the enclosure 110 of the computing rack architecture system 100 of FIGS. 1A-1E that is adapted to hold twelve modules 112 (See FIG. 1C). An important aspect to note is that the same type of modules 112 are structurally compatible with both the OCP 21 inch rack 106 and the EIA 19 inch rack 206. Additionally, because the OCP 21 inch rack 106 and EIA 19 inch rack 206 provide at least a portion of the structure of the enclosures 110 and 210, respectively, optimal use of the space with each rack 106, 206 is provided. Additionally, it may be important to note that the computing rack architecture system 100 and computing rack architecture system 200 may provide for any desired height for the modules 112. The only limitation with the desired height may be the type of mounting mechanisms used to mount the top guide plates 102, 202, bottom support plates 104, 204, power bus bars 116, 216, inlet direct liquid cooling (DLC) manifold 120a, 220a and outlet DLC manifolds 1220b, 220b to their respective racks 106, 206. For example, if a row of pre-drilled holes configured in a rack are 0.5 inches apart, then the desired height may exist in increments of 0.5 inches.

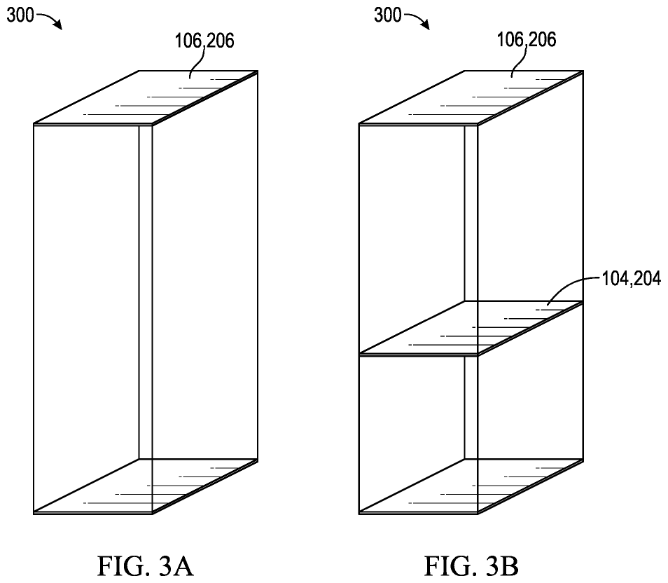

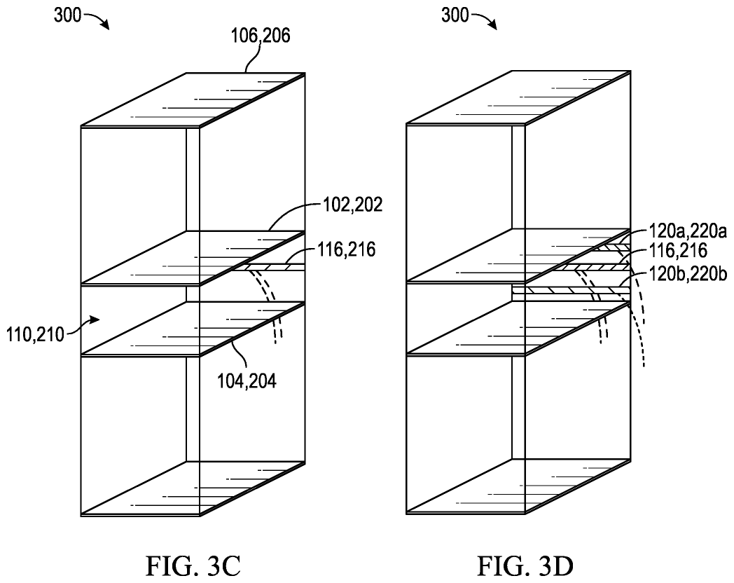

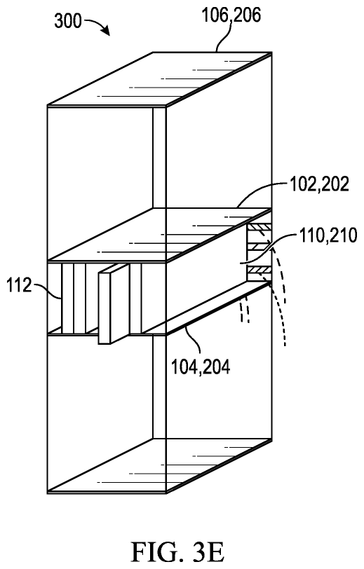

FIGS. 3A-3E illustrate an example computing rack architecture method 300 that may be performed to implement the computing rack architecture system 100, 200 in a computing rack according to one embodiment of the present disclosure. The computing rack architecture method 300 may be performed on any suitable computing rack. In one embodiment the computing rack architecture method 300 may be performed on an OCP 21 inch rack 106 as shown in FIGS. 1A-1E or on an EIA 19 inch rack as shown in FIGS. 2A-2B.

Initially at FIG. 3A, a rack is provided. As mentioned previously, the rack may be either an OCP 21 inch rack 106, or an EIA 19 inch rack 206. As shown on FIG. 3B, a bottom support plate 104, 204 is mounted inside the rack 106, 206. Next as shown on FIG. 3C, a top guide plate 102, 202 and a power bus bar 116, 216 is mounted onto the rack 106, 206. It may be important to note that no direct coupling of the bottom support plate 104, 204 and the top guide plate 102, 202 is provided. Rather the structure for the resulting enclosure formed between the bottom support plate 104, 204 and top guide plate 102, 202 is provided by the sides of the rack 106, 206.

As shown on FIG. 3D, an inlet DLC manifold 120a, 220a and an outlet DLC manifold 120b, 220b are mounted to the rack 106, 206. Thereafter as shown on FIG. 3E, modules 112 are inserted into the enclosure 112 formed between the bottom support plate 104, 204 top guide plate 102, 202 and sides of the rack 106, 206. The distance D2 between the bottom support plate 104, 204 and power bus bar 116, 216 are maintained by the structure of the rack 106, 206 so that complementary power connectors on each module 112 can be blind mated when it is inserted into the enclosure 110, 210. Likewise, the rack 106 maintains the hydraulic connectors 122a, 222a at a specified distance D3 from the top guide plate 102, 202, and the hydraulic connectors 122b, 222b at a specified distance D4 from the bottom support plate 104, 204 so that complementary hydraulic connectors on each module 112 can be blind mated when inserted.

The aforedescribed method 300 may be performed each time a row of modules 112 are to be deployed in the rack 106, 206. For example, the method 300 may be performed additional times to deploy additional rows of modules 112 above and/or below the previous row of deployed modules 112 in the rack 106, 206. As another example, the method 300 may be performed again to remove the modules 112 from one type of rack (e.g., OCP 21 inch rack), and deploy those same modules 112 in a different type of rack (e.g., EIA 19 inch rack). Nevertheless, when use of the method 300 is no longer needed or desired, the method 300 ends.

Although FIG. 3 describes one example of a method that may be performed to deploy modules 112 in different types of racks, the features of the disclosed process may be embodied in other specific forms without deviating from the spirit and scope of the present disclosure. For example, the method 300 may perform additional, fewer, or different operations than those operations as described in the present example. As another example, certain steps of the aforedescribed process may be performed in a different sequence than those operations as described in the present example.

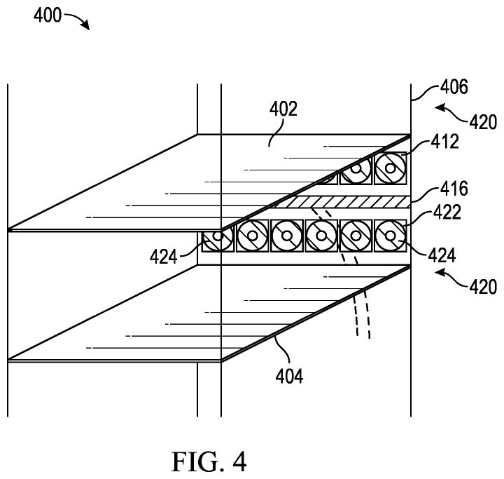

FIG. 4 illustrates an enlarged, partial, perspective view of another example computing rack architecture system 400 that may implement air cooling according to one embodiment of the present disclosure. The computing rack architecture system 400 includes a top guide plate 402, a bottom support plate 404, an enclosure 410, a power bus bar 416, and a rack 406 that are similar in design and construction to the top guide plate 102, a bottom support plate 104, enclosure 110, power bus bar 116, and rack 106 of the computing rack architecture system 100 of FIGS. 1A-1E. The computing rack architecture system 400 differs, however, in that it includes two cooling fan structures 420 rather than the inlet direct liquid cooling (DLC) manifold 220a and an outlet DLC manifold 220b cooling mechanism. Each cooling fan structure 420 includes brackets 422 for mounting on the rear side of the rack 406. The brackets 422 extend between each side of the rack 406 and have a number of cooling fans 424 mounted thereon for providing air cooling for the modules 112 when inserted into the enclosure 410. Thus, the cooling fan structures 420 may provide air cooling when DLC cooling is not available or is not needed.

FIG. 5 is a block diagram of components of an example IHS 500, which may be embodied as one or more of the modules 112 described herein above. As depicted, IHS 500 includes host processor(s) 501. In various embodiments, IHS 500 may be a single-processor system, a multi-processor system including two or more processors, and/or a heterogeneous computing platform. Host processor(s) 501 may include any processor capable of executing program instructions, such as a PENTIUM processor, or any general-purpose or embedded processor implementing any of a variety of Instruction Set Architectures (ISAs), such as an x86 or a Reduced Instruction Set Computer (RISC) ISA (e.g., POWERPC, ARM, SPARC, MIPS, etc.).

IHS 500 includes chipset 502 coupled to host processor(s) 501. Chipset 502 may provide host processor(s) 501 with access to several resources. In some cases, chipset 502 may utilize a QuickPath Interconnect (QPI) bus to communicate with host processor(s) 501.

Chipset 502 may also be coupled to communication interface(s) 505 to enable communications between IHS 500 and various wired and/or wireless networks, such as Ethernet, WiFi, BLUETOOTH (BT), cellular or mobile networks (e.g., Code-Division Multiple Access or “CDMA,” Time-Division Multiple Access or “TDMA,” Long-Term Evolution or “LTE,” etc.), satellite networks, or the like.

Communication interface(s) 505 may also be used to communicate with certain peripherals devices (e.g., BT speakers, microphones, headsets, etc.). Moreover, communication interface(s) 505 may be coupled to chipset 502 via a Peripheral Component Interconnect Express (PCIe) bus, or the like.

Chipset 502 may be coupled to display/touch controller(s) 504, which may include one or more Graphics Processor Units (GPUs) on a graphics bus, such as an Accelerated Graphics Port (AGP) or PCIe bus. As shown, display/touch controller(s) 504 provide video or display signals to one or more display device(s) 511.

Display device(s) 511 may include Liquid Crystal Display (LCD), Light Emitting Diode (LED), organic LED (OLED), or other thin film display technologies. Display device(s) 511 may include a plurality of pixels arranged in a matrix, configured to display visual information, such as text, two-dimensional images, video, three-dimensional images, etc. In some cases, display device(s) 511 may be provided as a single continuous display, or as two or more discrete displays.

Chipset 502 may provide host processor(s) 501 and/or display/touch controller(s) 504 with access to system memory 503. In various embodiments, system memory 503 may be implemented using any suitable memory technology, such as static RAM (SRAM), dynamic RAM (DRAM) or magnetic disks, or any nonvolatile/Flash-type memory, such as a solid-state drive (SSD) or the like.

Chipset 502 may also provide host processor(s) 501 with access to one or more Universal Serial Bus (USB) ports 508, to which one or more peripheral devices may be coupled (e.g., integrated or external webcams, microphones, speakers, etc.).

Chipset 502 may further provide host processor(s) 501 with access to one or more hard disk drives, solid-state drives, optical drives, or other removable-media drives 513.

Chipset 502 may also provide access to one or more user input devices 506, for example, using a super I/O controller or the like. Examples of user input devices 506 may include, but are not limited to, microphone(s) 514A, camera(s) 514B, and keyboard/mouse 514N. Other user input devices 506 may include a touchpad, trackpad, stylus or active pen, totem, etc.

Each user input devices 506 may include a respective controller (e.g., a touchpad may have its own touchpad controller) that interfaces with chipset 502 through a wired or wireless connection (e.g., via communication interfaces(s) 505). In some cases, chipset 502 may also provide access to one or more user output devices (e.g., video projectors, paper printers, 3D printers, loudspeakers, audio headsets, Virtual/Augmented Reality (VR/AR) devices, etc.). In certain embodiments, chipset 502 may further provide an interface for communications with hardware sensors 510.

Sensors 510 may be disposed on or within the chassis of IHS 500, or otherwise coupled to IHS 500, and may include, but are not limited to: electric, magnetic, radio, optical (e.g., camera, webcam, etc.), infrared, thermal (e.g., thermistors etc.), force, pressure, acoustic (e.g., microphone), ultrasonic, proximity, position, deformation, bending, direction, movement, velocity, rotation, gyroscope, Inertial Measurement Unit (IMU), and/or acceleration sensor(s).

The Unified Extensible Firmware Interface (UEFI) was designed as a successor to BIOS. As a result, many modern IHSs utilize UEFI in addition to or instead of a BIOS. As used herein, BIOS 507 is intended to also encompass a UEFI component.

Embedded Controller (EC) or Baseboard Management Controller (BMC) 509 is operational from the very start of each IHS power reset and handles various tasks not ordinarily handled by host processor(s) 501. Examples of these operations may include, but are not limited to: receiving and processing signals from a keyboard or touchpad, as well as other buttons and switches (e.g., power button, laptop lid switch, etc.), receiving and processing thermal measurements (e.g., performing fan control, CPU and GPU throttling, and emergency shutdown), controlling indicator LEDs (e.g., caps lock, scroll lock, number lock, battery, power, wireless LAN, sleep, etc.), managing PMU/BMU 512, alternating current (AC) adapter/Power Supply Unit (PSU) 515 and/or battery/current limiter 516, allowing remote diagnostics and remediation over network(s) 104, etc. For example, EC/BMC 509 may implement operations for interfacing with power adapter/PSU 515 in managing power for IHS 500. Such operations may be performed to determine the power status of IHS 500, such as whether IHS 500 is operating from AC adapter/PSU 515 and/or battery 516.

Firmware instructions utilized by EC/BMC 509 may also be used to provide various core operations of IHS 500, such as power management and management of certain modes of IHS 500 (e.g., turbo modes, maximum operating clock frequencies of certain components, etc.). In addition, EC/BMC 509 may implement operations for detecting certain changes to the physical configuration or posture of IHS 500. For instance, when IHS 500 is embodied as a 2-in-1 laptop/tablet form factor, EC/BMC 509 may receive inputs from a lid position or hinge angle sensor 510, and it may use those inputs to determine: whether the two sides of IHS 500 have been latched together to a closed position or a tablet position, the magnitude of a hinge or lid angle, etc. In response to these changes, the EC may enable or disable certain features of IHS 500 (e.g., front or rear facing camera, etc.).

In some cases, EC/BMC 509 may be configured to identify any number of IHS postures, including, but not limited to: laptop, stand, tablet, tent, or book. For example, when display(s) 511 of IHS 500 is open with respect to a horizontal keyboard portion, and the keyboard is facing up, EC/BMC 509 may determine IHS 500 to be in a laptop posture. When display(s) 511 of IHS 500 is open with respect to the horizontal keyboard portion, but the keyboard is facing down (e.g., its keys are against the top surface of a table), EC/BMC 509 may determine IHS 500 to be in a stand posture.

When the back of display(s) 511 is closed against the back of the keyboard portion, EC/BMC 509 may determine IHS 500 to be in a tablet posture. When IHS 500 has two display(s) 511 open side-by-side, EC/BMC 509 may determine IHS 500 to be in a book posture. When IHS 500 has two displays open to form a triangular structure sitting on a horizontal surface, such that a hinge between the displays is at the top vertex of the triangle, EC/BMC 509 may determine IHS 500 to be in a tent posture. In some implementations, EC/BMC 509 may also determine if display(s) 511 of IHS 500 are in a landscape or portrait orientation. In some cases, EC/BMC 509 may be installed as a Trusted Execution Environment (TEE) component to the motherboard of IHS 500.

Additionally, or alternatively, EC/BMC 509 may be configured to calculate hashes or signatures that uniquely identify individual components of IHS 500. In such scenarios, EC/BMC 509 may calculate a hash value based on the configuration of a hardware and/or software component coupled to IHS 500. For instance, EC/BMC 509 may calculate a hash value based on all firmware and other code or settings stored in an onboard memory of a hardware component.

Hash values may be calculated as part of a trusted process of manufacturing IHS 500 and may be maintained in secure storage as a reference signature. EC/BMC 509 may later recalculate the hash value for a component, compare it against the reference hash value to determine if any modifications have been made to the component, thus indicating that the component has been compromised. In this manner, EC/BMC 509 may validate the integrity of hardware and software components installed in IHS 500.

In various embodiments, IHS 500 may be coupled to an external power source (e.g., AC outlet or mains) through an AC adapter/PSU 515. AC adapter/PSU 515 may include an adapter portion having a central unit (e.g., a power brick, wall charger, or the like) configured to draw power from an AC outlet via a first electrical cord, convert the AC power to direct current (DC) power, and provide DC power to IHS 500 via a second electrical cord.

Additionally, or alternatively, AC adapter/PSU 515 may include an internal or external power supply portion (e.g., a switching power supply, etc.) connected to the second electrical cord and configured to convert AC to DC. AC adapter/PSU 515 may also supply a standby voltage, so that most of IHS 500 can be powered off after preparing for hibernation or shutdown, and powered back on by an event (e.g., remotely via wake-on-LAN, etc.). In general, AC adapter/PSU 515 may have any specific power rating, measured in volts or watts, and any suitable connectors.

IHS 500 may also include internal or external battery 516. Battery 516 may include, for example, a Lithium-ion or Li-ion rechargeable device capable of storing energy sufficient to power IHS 500 for an amount of time, depending upon the IHS's workloads, environmental conditions, etc. In some cases, a battery pack may also contain temperature sensors, voltage regulator circuits, voltage taps, and/or charge-state monitors. For example, battery 516 may include a current limiter, or the like.

In some embodiments, battery 516 may be configured to detect overcurrent or undervoltage conditions using Limits Management Hardware (LMH). As used herein, the term “overcurrent” refers to a condition in an electrical circuit that arises when a normal load current is exceeded (e.g., overloads, short circuits, etc.). Conversely, the term “undervoltage” refers to a condition (e.g., “brownout”) where the applied voltage drops to X % of rated voltage (e.g., 90%), or less, for a predetermined amount of time (e.g., 1 minute).

Power Management Unit (PMU) 512 governs power functions of IHS 500, including AC adapter/PSU 515 and battery 516. For example, PMU 512 may be configured to: monitor power connections and battery charges, charging batteries, control power to other components, devices, or ICs, shut down components when they are left idle, control sleep and power functions (On and Off), managing interfaces for built-in keypad and touchpads, regulate real-time clocks (RTCs), etc.

In some implementations, PMU 512 may include one or more Power Management Integrated Circuits (PMICs) configured to control the flow and direction or electrical power in IHS 500. Particularly, a PMIC may be configured to perform battery management, power source selection, voltage regulation, voltage supervision, undervoltage protection, power sequencing, and/or charging operations. It may also include a DC-to-DC converter to allow dynamic voltage scaling, or the like.

Additionally, or alternatively, PMU 512 may include a Battery Management Unit (BMU) (referred to collectively as “PMU/BMU 512”). AC adapter/PSU 515 may be removably coupled to a battery charge controller within PMU/BMU 512 to provide IHS 500 with a source of DC power from battery cells within battery 516 (e.g., a lithium ion (Li-ion) or nickel metal hydride (NiMH) battery pack including one or more rechargeable batteries). PMU/BMU 512 may include non-volatile memory and it may be configured to collect and store battery status, charging, and discharging information, and to provide that information to other IHS components.

Examples of information collected and stored in a memory within PMU/BMU 512 may include, but are not limited to: operating conditions (e.g., battery operating conditions including battery state information such as battery current amplitude and/or current direction, battery voltage, battery charge cycles, battery state of charge, battery state of health, battery temperature, battery usage data such as charging and discharging data; and/or IHS operating conditions such as processor operating speed data, system power management and cooling system settings, state of “system present” pin signal), environmental or contextual information (e.g., such as ambient temperature, relative humidity, system geolocation measured by GPS or triangulation, time and date, etc.), and BMU events.

Examples of BMU events may include, but are not limited to acceleration or shock events, system transportation events, exposure to elevated temperature for extended time periods, high discharge current rate, combinations of battery voltage, battery current and/or battery temperature (e.g., elevated temperature event at full charge and/or high voltage causes more battery degradation than lower voltage), etc.

In some embodiments, power draw measurements may be conducted with control and monitoring of power supply via PMU/BMU 512. Power draw data may also be monitored with respect to individual components or devices of IHS 500. Whenever applicable, PMU/BMU 512 may administer the execution of a power policy, or the like.

IHS 500 may also include one or more fans 517 configured to cool down one or more components or devices of IHS 500 disposed inside a chassis, case, or housing. Fan(s) 517 may include any fan inside, or attached to, IHS 500 and used for active cooling. Fan(s) 517 may be used to draw cooler air into the case from the outside, expel warm air from inside, and/or move air across a heat sink to cool a particular IHS component. In various embodiments, both axial and sometimes centrifugal (blower/squirrel-cage) fans may be used.

In other embodiments, IHS 500 may not include all the components shown in FIG. 5. In other embodiments, IHS 500 may include other components in addition to those that are shown in FIG. 5. Furthermore, some components that are represented as separate components in FIG. 5 may instead be integrated with other components, such that all or a portion of the operations executed by the illustrated components may instead be executed by the integrated component.

For example, in various embodiments described herein, host processor(s) 501 and/or other components of IHS 500 (e.g., chipset 502, display/touch controller(s) 504, communication interface(s) 505, EC/BMC 509, etc.) may be replaced by discrete devices within a heterogeneous computing platform. As such, IHS 500 may assume different form factors including, but not limited to: servers, workstations, desktops, laptops, appliances, video game consoles, tablets, smartphones, etc.

It should be understood that various operations described herein may be implemented in software executed by logic or processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

What is claimed is:

1. A computing rack architecture system comprising:
a first plate mounted to a computing rack; and
a second plate mounted to the computing rack at a specified distance from the first plate, wherein the first plate, the second plate, and sides of the computing rack comprise an enclosure that is configured to house a plurality of modules of an Information Handling System (IHS).

2. The computing rack architecture system of claim 1, wherein the first plate comprises a bottom support plate structured to support the weight of the modules.

3. The computing rack architecture system of claim 1, wherein the second plate comprises a top guide plate structured to guide the modules into and out of the enclosure.

4. The computing rack architecture system of claim 1, wherein the computing rack comprises at least one of an Electronics Industries Alliance (EIA) 19 inch rack or an Open Compute Project (OCP) 21 inch rack.

5. The computing rack architecture system of claim 4, wherein the modules are compatible with either the EIA 19 inch rack or the OCP 21 inch rack.

6. The computing rack architecture system of claim 1, further comprising an electrical power bus extending horizontally between the sides of the computing rack.

7. The computing rack architecture system of claim 6, wherein the sides of the computing rack maintain the electrical power bus at a specified distance from the first plate so that a complementary connector on each module can be blind mated with the electrical power bus when the module in inserted into the enclosure.

8. The computing rack architecture system of claim 1, further comprising an inlet Direct Liquid Cooling (DLC) manifold and an outlet DLC manifold extending horizontally between the sides of the computing rack.

9. The computing rack architecture system of claim 8, wherein the sides of the computing rack maintain the inlet and outlet DLC manifold at a specified distance from the first plate so that a pair of complementary hydraulic connectors on each module can be blind mated with the inlet and outlet DLC manifold when the module in inserted into the enclosure.

10. A computing rack architecture method comprising:
mounting a first plate mounted to a computing rack;
mounting a second plate mounted to the computing rack at a specified distance from the first plate, wherein the first plate, the second plate, and sides of the computing rack comprise an enclosure; and
inserting a plurality of modules of an Information Handling System (IHS) into the enclosure.

11. The computing rack architecture method of claim 10, further comprising supporting a weight of the modules using the first plate.

12. The computing rack architecture method of claim 10, further comprising guiding the modules into and out of the enclosure using the second plate.

13. The computing rack architecture method of claim 10, further comprising removing the modules from the enclosure; and
inserting the modules in an enclosure of another computing rack, wherein the other computing rack is a different type.

14. The computing rack architecture method of claim 10, further comprising mounting an electrical power bus extending horizontally between the sides of the computing rack.

15. The computing rack architecture method of claim 14, further comprising maintaining, using the sides of the computing rack, the electrical power bus at a specified distance from the first plate so that a complementary connector on each module can be blind mated with the electrical power bus when the module in inserted into the enclosure.

16. The computing rack architecture method of claim 10, further comprising mounting an inlet Direct Liquid Cooling (DLC) manifold and an outlet DLC manifold horizontally between the sides of the computing rack.

17. The computing rack architecture method of claim 16, further comprising maintaining, using the sides of the computing rack, the inlet and outlet DLC manifold at a specified distance from the first plate so that a pair of complementary hydraulic connectors on each module can be blind mated with the inlet and outlet DLC manifold when the module in inserted into the enclosure.

18. An Information Handling System (IHS) comprising:
a plurality of modules;
a first plate mounted to a computing rack; and
a second plate mounted to the computing rack at a specified distance from the first plate, wherein the first plate, the second plate, and sides of the computing rack comprise an enclosure that is configured to house the modules.

19. The IHS of claim 18, wherein the first plate comprises a bottom support plate structured to support the weight of the modules, and the second plate comprises a top guide plate structured to guide the modules into and out of the enclosure.

20. The IHS of claim 18, wherein the modules are compatible with either an Electronics Industries Alliance (EIA) 19 inch rack or an Open Compute Project (OCP) 21 inch rack.
